(19) United States
(12) Patent Application Publication
(10) Pub. No.: US 2025/0247094 A1
(43) Pub. Date: Jul. 31, 2025

(54) POWER EFFICIENT PREDRIVER WITH NMOS MULTIPLEXER

(71) Applicant: NVIDIA Corporation, Santa Clara, CA (US)

(72) Inventors: Steve Fang; David Chiong, South San Francisco, CA (US); Raj Anantha Rao, Fremont, CA (US)

(21) Appl. No.: 18/424,674

(22) Filed: Jan. 26, 2024

(51) Int. Cl. H03K 17/693; H03F 3/45; H03K 17/687

(52) U.S. Cl. CPC H03K 17/693; H03F 3/45475; H03K 17/6872

(57) ABSTRACT

A predriver circuit includes a voltage reference node, and a set of branches coupled to the voltage reference node. Each branch comprises a set of n-type metal-oxide semiconductor (NMOS) transistors. The predriver circuit further includes an active inductor coupled to the voltage reference node, and an amplifier. The input of the amplifier is coupled to the voltage reference node, and an output of the amplifier is coupled to a predriver output.

### TECHNICAL FIELD

At least one embodiment pertains to electrical system components, particularly active electrical components. For example, at least one embodiment pertains to a driver or predriver circuit for interfacing between two or more systems.

### BACKGROUND

In many electrical circuits—such as amplification circuits or data communication circuits, etc. —it is important that the electrical circuit is efficient and reliable. A driver circuit (e.g., which can include, or immediately follow a predriver circuit) can manage the flow of electrical current between electrically coupled components such that the inputs and outputs of various electrical component can maintain their respective appropriate voltage, current, and/or impedance values.

### BRIEF DESCRIPTION OF DRAWINGS

Various embodiments in accordance with the present disclosure will be described with reference to the drawings, in which:

FIG. 1 is a block diagram of an example system including a predriver with an NMOS multiplexer, according to aspects of the disclosure.

FIG. 2 is a block diagram of an example system including a predriver with an NMOS multiplexer, according to aspects of the disclosure.

FIG. 3 is a block diagram of an example system including a predriver with an NMOS multiplexer, according to aspects of the disclosure.

FIG. 4 is a schematic circuit diagram of an example predriver circuit, according to aspects of the disclosure.

FIG. 5 is a block diagram of an example system including a driver with an NMOS multiplexer, according to aspects of the disclosure.

FIG. 6 is a block diagram of an example system including a predriver, according to aspects of the disclosure.

FIG. 7 is a flow chart of an example method for operating a predriver with an NMOS multiplexer, according to aspects of the disclosure.

### DETAILED DESCRIPTION

Embodiments described herein are directed to reducing the power consumption of driver, and predriver circuits to improve electrical efficiency while maintaining circuit stability and reliability. A “driver circuit” can configured to have a certain output impedance, whereas a “predriver circuit” is not necessarily configured to have a certain output impedance. For example, and in at least one embodiment, a driver circuit can include a predriver circuit and an impedance matching circuit. For the sake of brevity, as used herein, the terms “driver circuit” or “driver” can inclusively refer to both a driver circuit (e.g., an impedance matched circuit) and a predriver circuit (a non-impedance matched circuit).

Many electrical systems can include one or more driver circuits. By way of non-limiting example, driver circuits can regulate the current provided to light-emitting-diodes (LEDs), control the speed and/or direction of an electromechanical motor, control one or more pixels represented by a display screen such as a liquid crystal display (LCD) or organic light-emitting diode (OLED) display, control transistor gates in circuits (e.g., in signal processing), to control data signals sent to speakers (e.g., audio signals), adjust and/or amplify sensor inputs (e.g., accelerometers, temperature sensors, gyroscope sensors, etc.), improve the signal-to-noise ratio of a signal (e.g., boosting a signal received at a receiver, or boosting a signal before transmitting the signal from a transmitter), and/or maintain the quality and integrity of high-speed data communication (e.g., such as Ethernet or peripheral component interconnect (PCI) data communications, etc.).

An important consideration for implementing a driver circuit is power consumption. Circuits (including driver circuits) can use active and/or passive components to adjust the voltages, currents, and impedances at various nodes of a circuit. As used herein, a “node” can refer to an electrical coupling of two or more electrical components. Circuit components (particularly passive components) can be inefficient and introduce power loss into the circuit. For example, a passive component like a resistor can be used to adjust the voltage, current, and/or impedance of a circuit node by converting excess electrical power into heat. In at least one embodiment, power losses in a driver circuit can be reduced by selecting, or configuring circuit components to use excess power that might be present in a circuit, instead of converting the excess power into a less usable form (e.g., heat, parasitic charges, etc.). Additionally, passive components can occupy a larger physical footprint or volume than active components, which can complicate trace routing and/or introduce other challenges (e.g., heat distribution, etc.).

Another important consideration for implementing a driver circuit is input and/or output adjusting (e.g., impedance matching, clock synchronization such as frequency matching and/or phase matching, etc.). For example, improper impedance into- or out of- a driver circuit can reduce signal integrity, and/or increase power consumption. In another example, improper clock synchronization can result in a time delay (e.g., latency increase) in the circuit to synchronize two or more clock signals (e.g., by adjusting the frequency, phase, etc. of the clock signals). Improper input and/or output adjustments can cause the circuit to be less power-efficient and/or reduce the potential performance of the circuit. For example, a CMOS-logic multiplexer can cause additional loading at the input of a driver circuit, even when previous stages have been loaded.

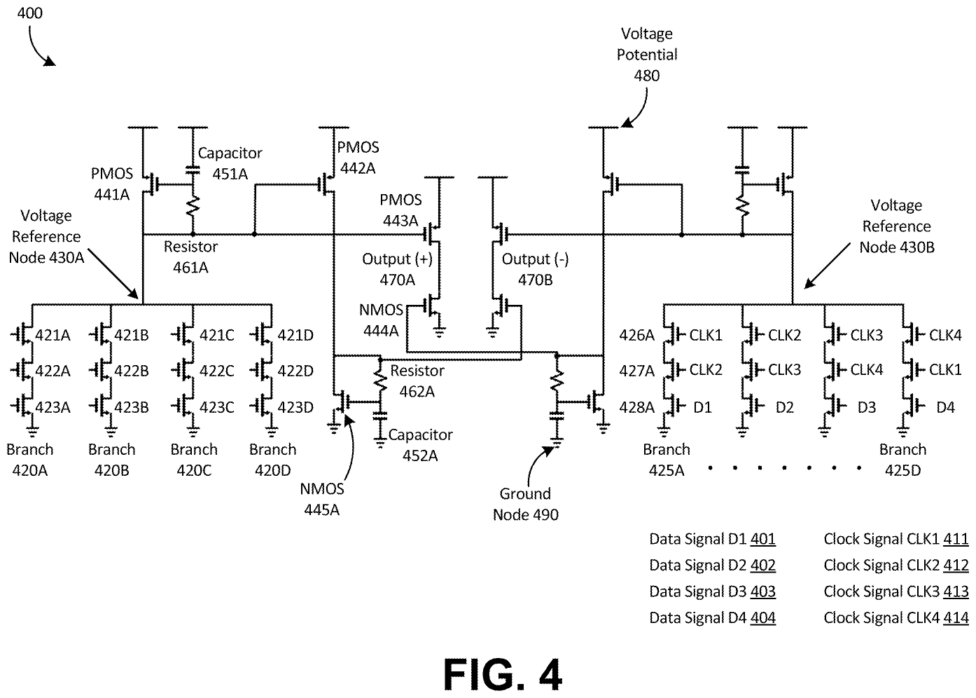

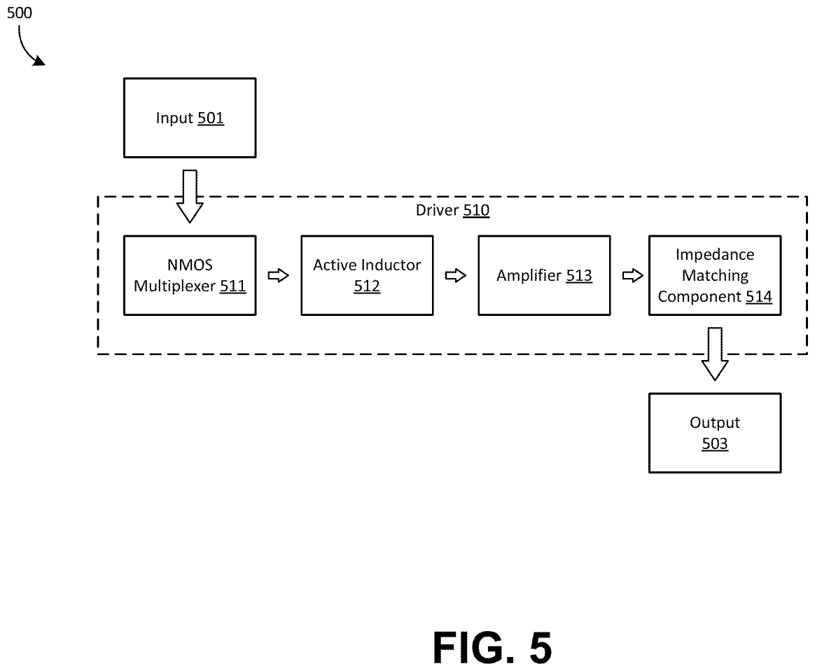

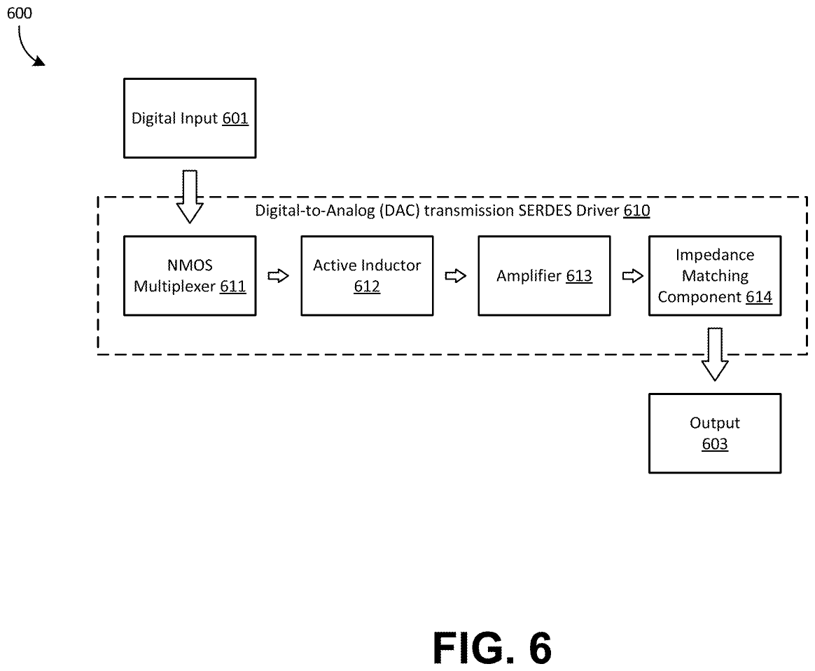

Aspects and embodiments of the disclosure address these and other challenges by providing a power efficient predriver with n-type metal-oxide semiconductor (NMOS) multiplexer for interfacing between electrically coupled components in an electrical circuit. The predriver can include an active inductor that is electrically coupled between the output of an NMOS multiplexer and an amplifier. The NMOS multiplexer can reduce the signal adjusting or input loading required for the predriver, and the incorporated active inductor can increase the power efficiency while decreasing the overall physical size of the driver circuit. In at least one embodiment, the schematic circuit diagram of a predriver circuit is described below in FIG. 4. In at least one embodiment, a driver with an NMOS multiplexer can include an impedance matching component, such as is described in FIG. 5. As described above, the predriver can be implemented in a variety of applications such as, for example, light or display controls, electromechanical controls, signal processing, signal adjusting, and/or communication applications (e.g., PCI communications), such as is described below in FIG. 6. In at least one embodiment, the predriver can be physically situated in the physical layout of a circuit board such that excess generated heat can be used to maintain certain operating adjusts for a portion of an integrated circuit.

Advantages of the disclosure include, but are not limited to, an increase in power efficiency of the predriver, a physical size reduction of the predriver, and/or a reduction in input loading requirements or signal adjusting requirements for the predriver circuit.

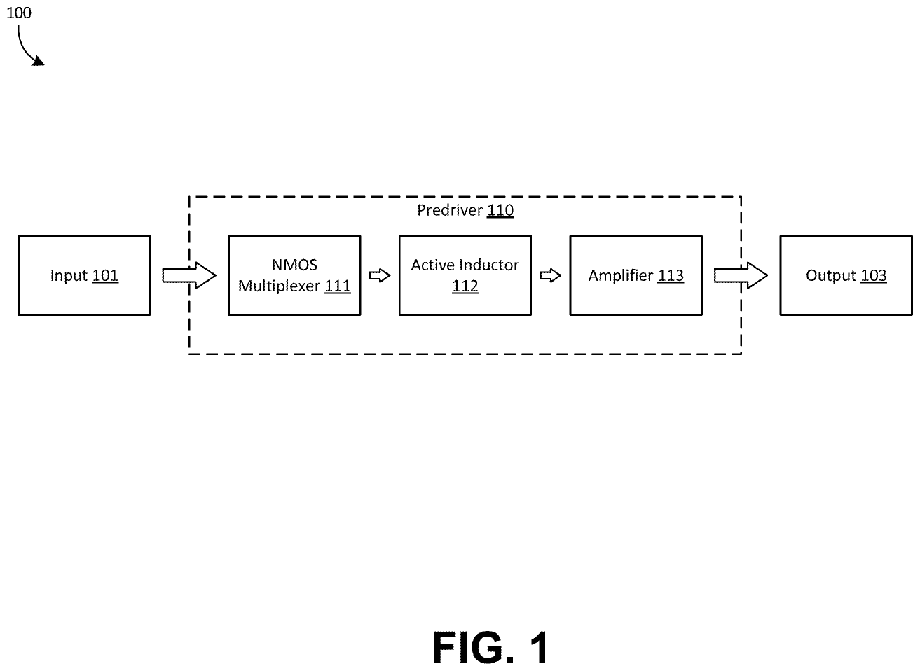

FIG. 1 is a block diagram of an example system, system 100 including a predriver, according to aspects of the disclosure. Predriver 110 can receive input 101, and generate output 103. Predriver 110 can include NMOS multiplexer 111, active inductor 112, and amplifier 113.

In at least one embodiment, input 101 can be received at NMOS multiplexer 111. NMOS multiplexer 111 can be a multiplexer that receives any number of signal inputs “X” and produces a single output based on any number of selector inputs “Y”. That is, in at least one embodiment, NMOS multiplexer 111 can be an “X:1” multiplexer, where X=2^{Y}. In at least one embodiment, NMOS multiplexer 111 can be an “X:1” multiplexer, where X is any integer greater than 1 (e.g., X>1).

In at least one example, inputs 101 can include one or more clock signals and one or more data signals. In at least one example, inputs 101 can include analog or digital signals, such as for example, audiovisual signals (e.g., audio, video, etc.), sensor input signals including biomedical signals (e.g., electrocardiogram (ECG), electroencephalogram (EEG), electromyogram (EMG), etc.), control signals (e.g., clock signals, indicator signals in control systems or feedback loops, electrical motor controls, etc.), pulse signals (e.g., pulse-width modulation signals), power signals (e.g., an alternating current (AC) or direct current (DC) power signal), communication signals (e.g., universal serial bus (USB) signals, PCI signals, etc.), electrical representations of optical signals, (e.g., an electrical signal generated from an optical signal by an optical transceiver, etc.) and/or composite signals that represent or include multiple signal types.

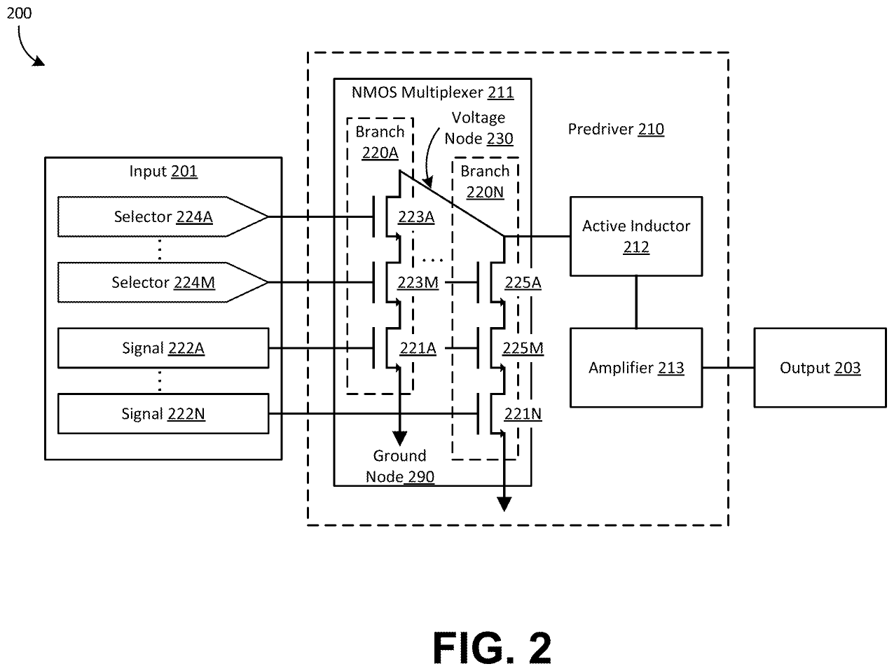

NMOS multiplexer 111 can use NMOS-logic to receive, gate, and produce two or more data signals from inputs 101. In at least one embodiment, NMOS multiplexer 111 uses NMOS transistors in a non-complimentary configuration (e.g., without p-type metal-oxide semiconductor (PMOS) transistors). Additional details regarding the NMOS-logic are described below in FIGS. 2-4.

Active inductor 112 can adjust the output of the NMOS multiplexer 111 for input to the amplifier 113. In at least one embodiment, active inductor 112 can include or couple to a current mirror that adjusts the output of the NMOS multiplexer. In at least one embodiment, the output of the NMOS multiplexer 111 can be adjusted by the active inductor 112 such that the signal received by the amplifier 113 permits the amplifier to produce a rail-to-rail output as an output 103. That is, the active inductor 112 can adjust the input signal to the amplifier 113 such that the output signal from of the amplifier 113 can have any voltage value between the negative power supply voltage and the positive power supply voltage of the amplifier.

In at least one embodiment, the active inductor 112 can be powered or controlled by excess power (e.g., current and voltage) from the NMOS multiplexer 111. For example, and in some embodiments, NMOS multiplexer 111 can produce an output that requires signal adjusting before it is used by a subsequent component (e.g., amplifier 113). While a passive component can be used to perform the signal adjusting, the passive component will often convert the electrical energy into less usable energy (e.g., heat), leading to inefficiencies in the circuit. In at least one embodiment, the signal adjusting can be performed using an active component (e.g., active inductor 112) that can consume less power to perform the same- or similar-signal adjusting as the passive component, while improving the adjustability and configurability of the predriver 110. In at least one embodiment, using NMOS-logic for the NMOS multiplexer produces excess power that can be used to power the active inductor 112, while simultaneously reducing the loading requirements for input 101 (e.g., signal adjusting requirements for input 101 before the input 101 is received by predriver 110). Additional details regarding the active inductor 112 and the interaction between the active inductor 112 and the NMOS multiplexer 111 are described below in FIGS. 2-4.

Amplifier 113 can receive a signal from active inductor 112 (e.g., an adjusted signal from NMOS multiplexer 111) and generate a rail-to-rail output as output 103. In at least one embodiment, amplifier 113 can be any amplifier that accepts an input signal, such as but not limited to, an operational amplifier, an audio amplifier, a radio- or microwave-frequency amplifier, a purpose-built amplifier (e.g., an instrumentation or calibration amplifier), a differential amplifier, a class A-, B-, AB-, or D-amplifier, a power amplifier, a logarithmic amplifier, and/or a current amplifier. In at least one embodiment, amplifier 113 can be a differential amplifier, such as is described below with reference to FIG. 4. In at least one embodiment, amplifier 113 can produce an output that is received by an impedance matching component, such as is described below with reference to FIG. 5.

Output 103 can be provided by predriver 110 to a load, such as any of the applications described above. In at least one embodiment, the load can be an impedance matching component. In at least one embodiment, the load can be a driver, such as is described below with reference to FIGS. 5-6.

FIG. 2 is a block diagram of an example system, system 200 that includes a predriver, according to aspects of the disclosure. System 200 includes predriver 210 which can receive input 201, and generate output 203 (e.g., predriver output). For the sake of brevity and clarity, aspects of input 201, predriver 210, and output 203 that are not described with reference to system 200 can be the same as, or similar to the aspects of input 101, predriver 110, and output 103 of FIG. 1, respectively.

In at least one embodiment, input 201 can include selector 224A through selector 224M (also referred to herein as “selectors 224A-M”) and signal 222A through signal 222N (also referred to herein as “signals 222A-N”, or “signal 222”). With reference to FIG. 1, in at least one embodiment, the quantity of signals 222A-N(e.g., “N”) can be equal to the number of signals “X”, and the quantity of selectors 224A-M (e.g., “M”) can be equal to the number of selectors “Y”. That is, NMOS multiplexer 211 can be a N:1 multiplexer, where N=2^{M}.

Returning to FIG. 2, as described above, input 201, including selectors 224A-M (e.g., selector lines) and signals 222A-N(e.g., data lines) can be any of various signal types. In embodiments, selectors 224A-M can be clock signals. In at least one embodiment, selector 224A can be a clock signal at a first phase, and selector 224M can be a clock signal at a second phase. In at least one embodiment, signals 222A-N can be data signals (e.g., communication signal such as PCI communication signals, etc.).

In at least one embodiment, NMOS multiplexer 211 can include branch 220A through branch 220N (also referred to herein as “branches 220A-N”, or “branch 220”) with each branch 220A-N coupling between a voltage node 230 and a ground node 290. Each branch 220 can respectively correspond to a signal 222. That is, branch 220A can correspond to signal 222A, branch 220N can correspond to signal 222N, etc. In at least one embodiment, branches 220A-N can include multiple NMOS transistors that correspond to each input 201. As illustrated in predriver 210, branch 220A includes NMOS 223A coupled to selector 224A, NMOS 223M coupled to selector 224M, and NMOS 221A coupled to signal 222A. Further, branch 220N includes NMOS 225A coupled to one of selector 224A-M, NMOS 225M coupled to another selector 224A-M, and NMOS 221N coupled to signal 222N. In at least one embodiment, selectors 224A-M respectively received at a branch 220 can be a clock signal at a first phase (e.g., received at NMOS 223A) and the clock signal at a second phase (e.g., received at NMOS 223M). Selectors 224A-M can be configured such that branches 220A-N are selected one at a time (e.g., on a rolling-basis). Additional details regarding interactions between the selectors 224A-M and signals 222A-N are described below with reference to FIG. 4.

In at least one embodiment, the values of signals 222A-N are summed at voltage node 230. In at least one embodiment, because each branch 220A-N is individually selected (e.g., only one branch 220A-N is activated at a time), minimal values of the remaining signals from signals 222A-N are summed with the value of signal 222A at voltage node 230 when branch 220A is activated. Similarly, minimal values of the signals remaining in signals 222A-N are summed with the value of signal 222N at voltage node 230 when branch 220N is activated. In at least one embodiment, active inductor 212 adjusts the signal at voltage node 230, and amplifier 213 receives the adjusted signal from voltage node 230 to generate output 203.

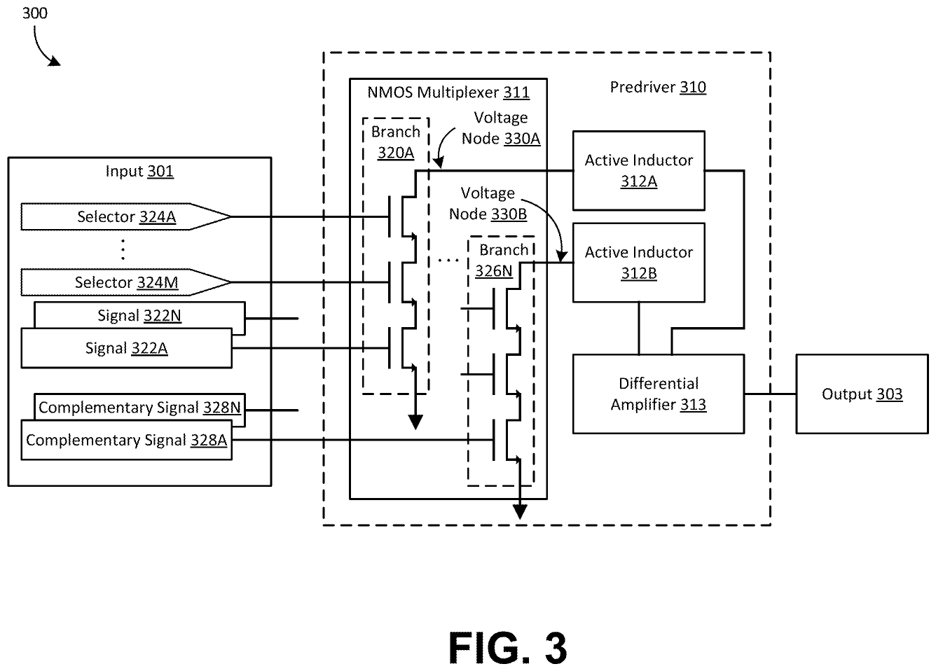

FIG. 3 is a block diagram of an example system, system 300 that includes a predriver, according to aspects of the disclosure. System 300 includes predriver 310, which can receive input 301, and generate output 303. For the sake of brevity and clarity, aspects of input 301-including selector 324A through selector 324M and signal 322A through signal 322N, predriver 310-including NMOS multiplexer 311 and branch 320A through branch 320N, and output 303 that are not described with reference to system 300 can be the same as, or similar to aspects of input 201, predriver 210, and output 203 of FIG. 2, respectively, except as described herein.

In at least one embodiment, input 301 can include selectors 324A-M, signals 322A-N and respective corresponding signals, complementary signal 328A through complementary signal 328N (also referred to herein as “complementary signals 328A-N), and NMOS multiplexer 311 can include branches 320A-N and branch 326A through branch 326N (also referred to herein as “branches 326A-N”). In at least one embodiment, branches 326A-N and complementary signals 328A-N can interact as described above in FIG. 2 with reference to signals 222A-N and branches 220A-N. In at least one embodiment, branches 320A-N and the respective branch of the complementary branches 326A-N can be selected simultaneously (e.g., with selector 324A-M). In an illustrated example, for the selection of “A”, voltage node 330A can reflect signal 322A, and voltage node 330B can reflect complementary signal 328A. In at least one embodiment (not illustrated), NMOS multiplexer 311 can be a first and a second NMOS multiplexer (e.g., predriver 310 can have separate NMOS multiplexers for signals 322A-N and complementary signals 328A-N respectively).

As described in FIG. 2 the active inductor respectively coupled to voltage nodes 330A-B (e.g., active inductor 312A and active inductor 312B respectively) can adjust the signal at each of the voltage nodes 330A-B. Returning to FIG. 3, each adjusted signal from the voltage nodes 330A-B can be received at differential amplifier 313.

As used herein, “differential amplifier” can refer to an electronic circuit that amplifies the difference between two input signals, while rejecting common-mode signals that are common to each input. Differential amplifier 313 can generate an output 303 based on the adjusted signals received from the active inductors 312A-B. In at least one embodiment, differential amplifier 313 can include a current mirror (not illustrated). In at least one embodiment, the current mirror can include active- and/or passive components configured to adjust the output impedance of the predriver 310 (e.g., at output 303). Additional details regarding the current mirror are describe below with reference to FIG. 4.

FIG. 4 is a schematic circuit diagram of an example predriver, predriver circuit 400, according to aspects of the disclosure. In at least one embodiment, predriver circuit 400 can refer to the same or similar circuitry as is included in predriver 310 of FIG. 3, predriver 210 of FIG. 2, and/or predriver 110 of FIG. 1. Accordingly, descriptions of components from FIGS. 1-3 can be used herein to aid in the description of the predriver circuit 400. For the sake of brevity and clarity, most of the complementary signal side of the predriver circuit 400 is not labeled or described because, with the exception of receiving a complementary signal, the complementary signal side performs the same functions as the signal side of the predriver circuit 400. Additional details are provided herein.

In at least one embodiment, predriver circuit 400 can accept data signal 401 through data signal 404 (also referred to herein as “D1 401,” “D2 402,” etc.) and clock signal 411 through clock signal 414 (also referred to herein as “CLK1 411,” “CLK2 412,” etc.) to produce output 470 based on positive output 470A and negative output 470B (also referred to herein collectively as “output 470”). In at least one embodiment, data signals 401-404 can be the same as, or similar to signals 323A-N of FIG. 3, and clock signals 411-414 can be the same as, or similar to selectors 324A-M.

Returning to FIG. 4, the NMOS multiplexer (e.g., NMOS multiplexer 311 of FIG. 3) is illustrated here as branches 420A-D, which each respectively include NMOS transistors 421-423. In at least one embodiment, NMOS transistors 421A-422D can be the same as, or similar to NMOS transistors 223A-M and NMOS transistors transistors 225A-M of FIG. 2, and NMOS transistors 423A-D can be the same as or similar to NMOS transistors 221A-N.

Returning to FIG. 4, as illustrated in the predriver circuit 400, branch 420A can receive CLK1 411 at the gate of NMOS transistor 421A, CLK2 412 at the gate of NMOS transistor 422A, and D1A 401A at the gate of NMOS transistor 423A. Branch 420B can receive CLK2 412 at the gate of NMOS transistor 421B, CLK3 413 at the gate of NMOS transistor 422B, and D2A 402A at the gate of NMOS transistor 423B. Branch 420C can receive CLK3 413 at the gate of NMOS transistor 421C, CLK4 414 at the gate of NMOS transistor 422C, and D3A 403A at the gate of NMOS transistor 423C. Branch 420D can receive CLK4 414 at the gate of NMOS transistor 421D, CLK1 411 at the gate of NMOS transistor 422D, and D4A 404A at the gate of NMOS transistor 423D. Similarly, on the complementary signal side, branch 425A can receive CLK1 411 at the gate of NMOS transistor 426A, CLK2 412 at the gate of NMOS transistor 427A, and D1B 401B at the gate of NMOS transistor 428A, etc., through to branch 425D. It can be noted that while the signal side (e.g., the “A” side) can receive data signals 401A-404A and the complementary signal side (e.g., the “B” side) can receive complementary data signals 401B-404B, each side receives the same clock signal 411-414 at each respective branch. Illustratively, D1A 401A and D1B 401B are both gated by clock signals 411-412. As used herein, “complementary pair” can be used to refer to two signals that are opposite or “inverted” from each other (e.g., a “signal” and a “complementary signal”). For example, and in at least one embodiment, a complementary data signal can be phase shifted (but not time shifted) by 180 degrees from a data signal.

In at least one embodiment, each clock signal 411-414 can be a different phase of the same clock signal. For example, CLK1 411 can have a first phase, CLK2 412 can have a second phase, CLK3 413 can have third phase, and CLK4 can have a fourth phase. In at least one embodiment, the clock signals 411-414 can each be 90 degrees out of phase from the next clock signal. That is, CLK1 411 can have a phase shift of 0 degrees, CLK2 412 can have a phase shift of 90 degrees, CLK3 413 can have a phase shift of 180 degrees, and CLK3 can have a phase shift of 270 degrees. In at least one embodiment, each branch 420 can receive two selector signals (e.g., clock signals 411-414) that are phase-shifted such that together the phase-shifted clock signals generate a “pulse” that enables the input signal (e.g., data signals 401-404) to be received at the voltage reference nodes 430A-B.

In the illustrative example, each of the selector signals are phase-shifted by +90 degrees (e.g., 0-90 degrees for branch 420A, 90-180 degrees for branch 420B, 180-270 degrees for branch 420C, 270-360 degrees for branch 420D, etc.). Thus, for a given clock signal, each of the branches will be activated at different intervals (e.g., rolling, or sequential intervals from branch 420A-D) by the pulse resulting from the two input clock signals at the given branch.

Voltage reference node 430A can sum the values of the branches 420A-D. Similarly, voltage reference node 430B can sum the values of the branches 425A-D. Voltage reference nodes 430A-B can be the same as, or similar to voltage reference nodes 330A-B of FIG. 3. As described above, the values of signals from non-selected branches 420A-D or 425A-D can be minimal in comparison to the value of the signal from the selected branch, thus minimally affecting the sum of the signals at respective voltage reference nodes 430A-B.

The signal at voltage reference nodes 430A-B can be adjusted by an active inductor (e.g., active inductor 312A of FIG. 3) as an input to the amplifier (e.g., differential amplifier 313). In predriver circuit 400, the active inductor is represented by PMOS transistor 441A, capacitor 451A, and resistor 461A. The voltage reference node 430A is coupled to the drain of PMOS transistor 441A, and the gate of PMOS transistor 441A is coupled between capacitor 451A and resistor 461A. Capacitor 451A and resistor 461A are coupled in series between a voltage source 480 and the voltage reference node 430A. It can be noted that this configuration of the active inductor is only illustrative, and that other configurations are possible. In this configuration, PMOS transistor 441A can be powered (at least in part) by the signal at voltage reference node 430A while the active inductor simultaneously adjusts the signal for input to the amplifier portion of the circuit (e.g., differential amplifier 313). With PMOS transistor 441A receiving power from the output of the collection of NMOS branches (e.g., branches 420A-D), signal power can be conserved, while enabling a lower loading requirement at the inputs to each respective NMOS branch (e.g., at the gates of 423A-D).

In at least one embodiment, the amplifier portion of the predriver circuit 400 (e.g., differential amplifier 313 of FIG. 3) can include a current mirror. In predriver circuit 400, the signal side of the current mirror is represented by PMOS transistor 442A, NMOS transistor 445A, resistor 462A, and capacitor 452A, with respective similar components on the complementary signal side of predriver circuit 400. The current mirror can be configured with active and passive components that can cause the differential amplifier (e.g., differential amplifier 313 of FIG. 3) to have the same- or similar currents on each side of the amplifier (e.g., the signal side and the complementary signal side). In at least one embodiment, the current mirror can include components that can cause the output of the predriver circuit 400 (e.g., the output at the amplifier) to satisfy a certain impedance value.

In at least one embodiment, the signal side of the amplifier portion of predriver circuit 400 can further include PMOS transistor 443A coupled to NMOS transistor 444A. PMOS transistor 443A and NMOS transistor 444A can be coupled by respective drains. The source of PMOS transistor 443A can be coupled to a voltage source 480, and the source of NMOS transistor 444A can be coupled to a ground node 490. It can be noted that as described above, the complementary signal side of this portion of predriver circuit 400 can include similar components configured to perform similar functions with a complementary signal.

In at least one embodiment, capacitor 451A coupled to resistor 461A can be used in conjunction with capacitor 452A and resistor 462A to bias the output 470 from the predriver. That is, the values of each capacitor 451-452A and each resistor 461-462A can adjust the center point value of the output 470. In at least one embodiment, the values of capacitors 451-452A and each resistors 461-462A are such that the center point value of the output 470 is halfway between the negative power supply value, and the positive power supply value.

FIG. 5 is a block diagram of an example system, system 500 including a driver 510 with an NMOS multiplexer, according to aspects of the disclosure. Driver 510 can process an input 501 and generate an output 503. Driver 510 can include NMOS multiplexer 511, active inductor 512, amplifier 513, and impedance matching component 514. For the sake of brevity and clarity, aspects of input 501, predriver 110-including NMOS multiplexer 511, active inductor 512, and amplifier 513 that are not described with reference to system 500 can be the same as, or similar to the aspects of input 301, predriver 310, NMOS multiplexer 311, active inductors 312A-B, and differential amplifier 313 of FIG. 3, respectively.

In at least one embodiment, impedance matching component 514 can receive an output from amplifier 513. The impedance matching component 514 can adjust the impedance output of the driver 510 to improve the maximum the output signal power transfer, and minimize the output signal reflections. In at least one embodiment, the impedance matching component 514 can include one or more inductors (L) and/or one or more capacitors (C). In at least one embodiment, the impedance matching component 514 can include one or more electrical traces of certain lengths, widths, shapes, and configurations (e.g., also referred to as “stub matching,” such as for a transmission line). In at least one embodiment, the impedance matching component 514 can be configured to perform quarter-wave impedance matching with one or more transmission lines or segments. In at least one embodiment, the impedance matching component 514 can include other passive and/or active electrical components, such as a balun, or radio frequency (RF) choke.

In at least one embodiment, the driver 510 can be part of a circuit in a serializer/deserializer (SERDES) device. In at least one embodiment, the driver 510 can be a part of a circuit that transmits and/or receives PCI data communications (e.g., PCI Express 6.0, 7.0, etc.). In at least one embodiment, the driver 510 can be part of a circuit in a digital-to-analog converter (DAC). In at least one embodiment, the driver 510 can be part of a transmission circuit, such as in a wireless RF transmitter, a signal generator, a transceiver, etc. In at least one embodiment, the driver 510 can be part of a DAC transmission circuit (e.g., a digital to analog conversion and signal transmission circuit). In at least one embodiment, the driver 510 can be part of a signal processing circuit.

An example system, system 600 including a driver (such as driver 510) is found in FIG. 6, which illustrates a block diagram of the system 600 including a DAC transmission SERDES driver 610, according to aspects of the disclosure. DAC transmission SERDES driver 610 use NMOS multiplexer 611, active inductor 612, amplifier 613, and impedance matching component 614 to produce an output 603 from a digital input 601.

In at least one embodiment, the digital input 601 can include one or more clock signals (e.g., selectors 324A-M of FIG. 3), and one or more signals (e.g., signals 322A-N). In at least one embodiment, DAC transmission SERDES driver 610 can generate a complementary signal for a signal include in the digital input 601. In at least one embodiment, the digital input 601 can additionally include one or more complementary signals (e.g., complementary signals 328A-N) that correspond to respective signals in the digital input 601.

Returning to FIG. 5, in at least one embodiment, the driver 510 can be implemented in a computer system environment as part of one or more computer components, such as in a central processing unit (CPU), a graphics processing unit (GPU), a data processing unit (DPU), an application-specific integrated circuit (ASIC), such as Tensorflow® Processing Unit from Google, an inference processing unit (IPU) from Graphcore™, or a Nervana® (e.g., “Lake Crest”) processor from Intel Corp or the like. In at least one embodiment, the driver 510 can be implemented in a machine-learning specific chip architecture used for training a machine learning model and/or using a trained machine learning model. In at least one embodiment, driver 510 can be implemented in embedded applications such as a microcontroller, a field programmable gate array (FPGA), a digital signal processor (DSP), an analog-to-digital converter (ADC) or any other system that can perform one or more similar functions.

In at least one embodiment, driver 510 can be implemented in a game console, including a game and media console, a mobile gaming console, a handheld came console or an online game console. In at least one embodiment, driver 510 can be implemented handheld devices, such as in a mobile phone, smartphone, tablet computing device, a mobile Internet device, or a digital camera. In at least one embodiment, driver 510 can be implemented in a wearable device, such as a smart watch wearable device, smart eyewear device, augmented reality device, or virtual reality device. In at least one embodiment, SERDES can be implemented in a television or set-top box device. In at least one embodiment, driver 510 can be implemented in handheld devices, such as in a

In at least one embodiment, the driver 510 can be implemented in a computer networking, or datacenter environment. The driver 510 can be implemented in devices configured to connect to a local area network (LAN), wide area network (WAN), a wired network (e.g., Ethernet network), a wireless network (e.g., an 802.11 network or wireless fidelity (Wi-Fi) network, a Bluetooth instance between connected devices, etc.), a cellular network (e.g., a Long Term Evolution (LTE) network), routers, hubs, switches, server computers, and/or a combination thereof. In at least one embodiment, the driver 510 can be implemented in high-speed intra datacenter communication networking, including optical communication networking (e.g., using fiber optical communication standards).

In at least one embodiment, the driver 510 can be implemented in storage systems, such as in a volatile or non-volatile memory device. For example, a volatile memory device can include, without limitation, a Dynamic Random Access Memory (DRAM) device or a Static Random Access Memory device (SRAM). Further, a non-volatile memory device can include a flash memory device, or a hard disk drive (HDD) memory device.

In at least one embodiment, the driver 510 can be implemented in high-speed or high-bandwidth data communication systems. For example, the driver 510 can be used in systems designed to communicate over a PCI Express (PCIe) bus (including versions 1.0-7.0, etc.), an Inter-Integrated Circuit (I2C) bus, a System Management Bus (SMBus), a Low Pin Count (LPC) bus, a Serial Peripheral Interface (SPI), a High Definition Audio (HAD) bus, a Serial Advance Technology Attachment (SATA) bus, a Universal Serial Bus (USB) (including versions 1.0-4.0) or a Universal Asynchronous Receiver/Transmitter (UART) bus. In at least one embodiment, the driver 510 can be implemented in a System on a Chip (SoC).

In at least one embodiment, the driver 510 can be implemented in automotive systems, such as advanced driver-assistance systems (ADAS), inter- and intra-vehicle communication networks, etc.

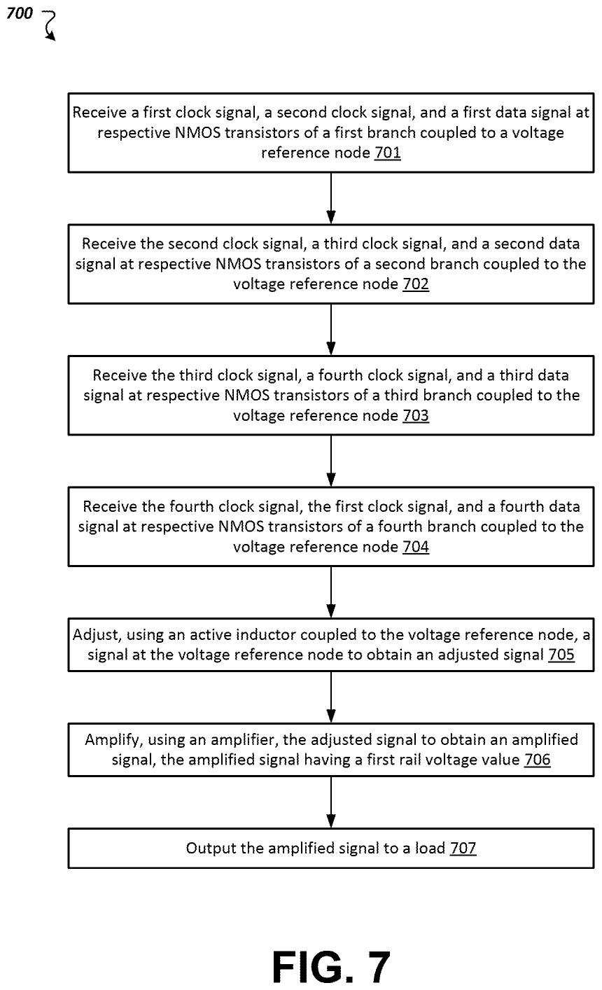

FIG. 7 is a flow chart of an example method for operating the predriver with NMOS multiplexer of FIGS. 1-6, according to aspects of the disclosure. The method 700 can be performed by processing logic comprising hardware, software, firmware, or any combination thereof. For example, the method 700 can be performed by the predriver circuit 400 of FIG. 4.

Although shown in a particular sequence or order, unless otherwise specified, the order of the processes can be modified. Thus, the illustrated embodiments should be understood only as examples, and the illustrated processes can be performed in a different order, and some processes can be performed in parallel. Additionally, one or more processes can be omitted in various embodiments. Thus, not all processes are required in every embodiment. Other process flows are possible.

At operation 701, the first clock signal, a second clock signal, and a first data signal are received at respective NMOS transistors of a first branch coupled to a voltage reference node.

At operation 702, a second clock signal, a third clock signal, and a second data signal are received at respective NMOS transistors of a second branch coupled to the voltage reference node.

At operation 703, a third clock signal, a fourth clock signal, and a third data signal are received at respective NMOS transistors of a third branch coupled to the voltage reference node.

At operation 704, a fourth clock signal, the first clock signal, and a fourth data signal are received at respective NMOS transistors of a fourth branch coupled to the voltage reference node.

At operation 705, a signal at the voltage reference node is adjusted using an active inductor coupled to the voltage reference node to obtain an adjusted signal.

At operation 706, the adjusted signal is amplified using an amplifier to obtain an amplified signal, the amplified signal having a first rail voltage value.

At operation 707, the amplified signal is output to a load. In at least one embodiment, the load can be a driver circuit. In at least one embodiment, the load can be an impedance matching circuit.

In at least one embodiment, the amplifier can be an amplifier that receives two inputs, such as a differential amplifier (e.g., differential amplifier 313 of FIG. 3). In such embodiments, the first clock signal, the second clock signal, and a fifth data signal are received at respective NMOS transistors of a first branch coupled to a second voltage reference node. Further, the second clock signal, the third clock signal, and a sixth data signal are received at respective NMOS transistors of a second branch coupled to the second voltage reference node. Further, the third clock signal, the fourth clock signal, and a seventh data signal are received at respective NMOS transistors of a third branch coupled to the second voltage reference node. Further, the fourth clock signal, the first clock signal, and an eighth data signal are received at respective NMOS transistors of a fourth branch coupled to the second voltage reference node. The second signal at the voltage reference node can be adjusted using a second active inductor coupled to the second voltage reference node to obtain a second adjusted signal. The second adjusted signal can be amplified using the amplifier to obtain a second amplified signal, the second amplified signal having a second rail voltage value. In at least one embodiment, the second amplified signal can be concurrently output to the load.

Other variations are within the spirit of the present disclosure. Thus, while disclosed techniques are susceptible to various modifications and alternative constructions, certain illustrated embodiments thereof are shown in drawings and have been described above in detail. It should be understood, however, that there is no intention to limit the disclosure to a specific form or forms disclosed, on the contrary, the intention is to cover all modifications, alternative constructions, and equivalents falling within the spirit and scope of the disclosure, as defined in appended claims.

Use of terms “a” and “an” and “the” and similar referents in the context of describing disclosed embodiments (especially in the context of following claims) are to be construed to cover both singular and plural, unless otherwise indicated herein or clearly contradicted by context, and not as a definition of a term. Terms “comprising,” “having,” “including,” and “containing” are to be construed as open-ended terms (meaning “including, but not limited to,”) unless otherwise noted. The term “connected,” when unmodified and referring to physical connections, is to be construed as partly or wholly contained within, attached to, or joined together, even if there is something intervening. Recitations of ranges of values herein are merely intended to serve as a shorthand method of referring individually to each separate value falling within the range, unless otherwise indicated herein, and each separate value is incorporated into the specification as if it were individually recited herein. Use of the term “set” (e.g., “a set of items”) or “subset,” unless otherwise noted or contradicted by context, is to be construed as a nonempty collection comprising one or more members. Further, unless otherwise noted or contradicted by context, the term “subset” of a corresponding set does not necessarily denote a proper subset of the corresponding set, but the subset and corresponding set can be equal.

Conjunctive language, such as phrases of the form “at least one of A, B, and C,” or “at least one of A, B, and C,” unless specifically stated otherwise or otherwise clearly contradicted by context, is otherwise understood with the context as used in general to present that an item, term, etc., can be either A or B or C, or any nonempty subset of a set of A and B and C. For instance, in an illustrative example of a set having three members, conjunctive phrases “at least one of A, B, and C” and “at least one of A, B, and C” refer to any of the following sets: {A}, {B}, {C}, {A, B}, {A, C}, {B, C}, {A, B, C}. Thus, such conjunctive language is not generally intended to imply that certain embodiments require at least one of A, at least one of B, and at least one of C each to be present. In addition, unless otherwise noted or contradicted by context, the term “plurality” indicates a state of being plural (e.g., “a plurality of items” indicates multiple items). A plurality is at least two items but can be more when so indicated either explicitly or by context. Further, unless stated otherwise or otherwise clear from context, the phrase “based on” means “based at least in part on” and not “based solely on.”

Operations of processes described herein can be performed in any suitable order unless otherwise indicated herein or otherwise clearly contradicted by context. In some embodiments, a process such as those processes described herein (or variations and/or combinations thereof) is performed under the control of one or more computer systems configured with executable instructions and is implemented as code (e.g., executable instructions, one or more computer programs or one or more applications) executing collectively on one or more processors, by hardware or combinations thereof. In some embodiments, code is stored on a computer-readable storage medium, for example, in form of a computer program comprising a plurality of instructions executable by one or more processors. In some embodiments, a computer-readable storage medium is a non-transitory computer-readable storage medium that excludes transitory signals (e.g., a propagating transient electric or electromagnetic transmission) but includes non-transitory data storage circuitry (e.g., buffers, cache, and queues) within transceivers of transitory signals. In some embodiments, code (e.g., executable code or source code) is stored on a set of one or more non-transitory computer-readable storage media having stored thereon executable instructions (or other memory to store executable instructions) that, when executed (i.e., as a result of being executed) by one or more processors of a computer system, cause a computer system to perform operations described herein. A set of non-transitory computer-readable storage media, in some embodiments, comprises multiple non-transitory computer-readable storage media and one or more of individual non-transitory storage media of multiple non-transitory computer-readable storage media lacks all of the code while multiple non-transitory computer-readable storage media collectively store all of the code. In some embodiments, executable instructions are executed such that different instructions are executed by different processors—for example, a non-transitory computer-readable storage medium stores instructions, and a main central processing unit (CPU) executes some of the instructions while a graphics processing unit (GPU) executes other instructions. In some embodiments, different components of a computer system have separate processors, and different processors execute different subsets of instructions.

Accordingly, in some embodiments, computer systems are configured to implement one or more services that singly or collectively perform operations of processes described herein, and such computer systems are configured with applicable hardware and/or software that enable the performance of operations. Further, a computer system that implements at least one embodiment of present disclosure is a single device and, in another embodiment, is a distributed computer system comprising multiple devices that operate differently such that distributed computer system performs operations described herein and such that a single device does not perform all operations.

Use of any and all examples or exemplary language (e.g., “such as”) provided herein is intended merely to better illuminate embodiments of the disclosure and does not pose a limitation on the scope of the disclosure unless otherwise claimed. No language in the specification should be construed as indicating any non-claimed element as essential to the practice of the disclosure.

All references, including publications, patent applications, and patents, cited herein are hereby incorporated by reference to the same extent as if each reference were individually and specifically indicated to be incorporated by reference and were set forth in its entirety herein.

In description and claims, the terms “coupled” and “connected,” along with their derivatives, can be used. It should be understood that these terms cannot be intended as synonyms for each other. Rather, in particular examples, “connected” or “coupled” can be used to indicate that two or more elements are in direct or indirect physical or electrical contact with each other. “Coupled” can also mean that two or more elements are not in direct contact with each other but yet still co-operate or interact with each other.

Unless specifically stated otherwise, it can be appreciated that throughout specification terms such as “processing,” “computing,” “calculating,” “determining,” or like, refer to action and/or processes of a computer or computing system or similar electronic computing device, that manipulates and/or transform data represented as physical, such as electronic, quantities within computing system's registers and/or memories into other data similarly represented as physical quantities within computing system's memories, registers or other such information storage, transmission or display devices.

In a similar manner, the term “processor” can refer to any device or portion of a device that processes electronic data from registers and/or memory and transform that electronic data into other electronic data that can be stored in registers and/or memory. As non-limiting examples, a “processor” can be a CPU or a GPU. A “computing platform” can comprise one or more processors. As used herein, “software” processes can include, for example, software and/or hardware entities that perform work over time, such as tasks, threads, and intelligent agents. Also, each process can refer to multiple processes for carrying out instructions in sequence or in parallel, continuously, or intermittently. The terms “system” and “method” are used herein interchangeably insofar as a system can embody one or more methods, and methods can be considered a system.

In the present document, references can be made to obtaining, acquiring, receiving, or inputting analog or digital data into a subsystem, computer system, or computer-implemented machine. Obtaining, acquiring, receiving, or inputting analog and digital data can be accomplished in a variety of ways, such as by receiving data as a parameter of a function call or a call to an application programming interface. In some implementations, the process of obtaining, acquiring, receiving, or inputting analog or digital data can be accomplished by transferring data via a serial or parallel interface. In another implementation, the process of obtaining, acquiring, receiving, or inputting analog or digital data can be accomplished by transferring data via a computer network from providing entity to acquiring entity. References can also be made to providing, outputting, transmitting, sending, or presenting analog or digital data. In various examples, the process of providing, outputting, transmitting, sending, or presenting analog or digital data can be accomplished by transferring data as an input or output parameter of a function call, a parameter of an application programming interface, or an interprocess communication mechanism.

Although the discussion above sets forth example implementations of described techniques, other architectures can be used to implement described functionality and are intended to be within the scope of this disclosure. Furthermore, although specific distributions of responsibilities are defined above for purposes of discussion, various functions and responsibilities might be distributed and divided in different ways, depending on circumstances.

Furthermore, although the subject matter has been described in language specific to structural features and/or methodological acts, it is to be understood that subject matter claimed in appended claims is not necessarily limited to specific features or acts described. Rather, specific features and acts are disclosed as exemplary forms of implementing the claims.

What is claimed is:

1. A predriver comprising:
a voltage reference node;
a set of branches coupled to the voltage reference node, wherein each branch comprises a set of n-type metal-oxide semiconductor (NMOS) transistors;
an active inductor coupled to the voltage reference node; and
an amplifier, wherein an input of the amplifier is coupled to the voltage reference node, and an output of the amplifier is coupled to a predriver output.

2. The predriver of claim 1, wherein the set of NMOS transistors of a first branch of the set of branches comprises:
a first NMOS transistor coupled to a first selector line;
a second NMOS transistor coupled to a second selector line; and
a third NMOS transistor coupled to a first data line, wherein the first NMOS transistor, the second NMOS transistor, and the third NMOS transistor are coupled in series between the voltage reference node and a ground node as a first series.

3. The predriver of claim 2, wherein the first NMOS transistor is to receive a clock signal on the first selector line, the second NMOS transistor is to receive a phase-shifted clock signal on the second selector line, and the third NMOS transistor is to receive a first data signal on the first data line.

4. The predriver of claim 2, wherein the set of NMOS transistors of a second branch of the set of branches comprises:
a fourth NMOS transistor coupled to the second selector line;
a fifth NMOS transistor coupled to a third selector line; and
a sixth NMOS transistor coupled to a second data line, wherein the fourth NMOS transistor, the fifth NMOS transistor, and the sixth NMOS transistor are coupled in series as a second series between the voltage reference node and the ground node as a second series, and wherein the first series is coupled in parallel with the second series.

5. The predriver of claim 4, wherein the fourth NMOS transistor is to receive a clock signal on the second selector line, the fifth NMOS transistor is to receive a phase-shifted clock signal on the third selector line, and the sixth NMOS transistor is to receive a second data signal on the second data line.

6. The predriver of claim 2, wherein the amplifier is a differential amplifier comprising a second input and a second output, the second output coupled to a second predriver output, the predriver further comprising:
a second voltage reference node coupled to the second input;
a second set of branches coupled to the second voltage reference node, wherein each second branch comprises a set of NMOS transistors; and
a second active inductor coupled to the second voltage reference node.

7. The predriver of claim 6, wherein the set of NMOS transistors of a first branch of the second set of branches comprises:
a fourth NMOS transistor coupled to the first selector line;
a fifth NMOS transistor coupled to the second selector line; and
a sixth NMOS transistor coupled to a second data line, wherein the fourth NMOS transistor, the fifth NMOS transistor, and the sixth NMOS transistor are coupled in series between the voltage reference node and the ground node.

8. The predriver of claim 1, wherein the active inductor comprises:
a capacitor and a resistor coupled in series between a first voltage source and the voltage reference node; and
a p-type metal-oxide semiconductor (PMOS) transistor coupled between the first voltage source and the voltage reference node, the PMOS transistor comprising a gate coupled to a node between the capacitor and the resistor.

9. The predriver of claim 1, further comprising an impedance matching component coupled to the output of the amplifier.

10. A system comprising:
a driver; and
a predriver coupled to the driver, wherein the predriver comprises:
a voltage reference node;
a set of branches coupled to the voltage reference node, wherein each branch comprises a set of n-type metal-oxide semiconductor (NMOS) transistors;
an active inductor coupled to the voltage reference node; and
an amplifier, wherein an input of the amplifier is coupled to the voltage reference node, and an output of the amplifier is coupled to an input of the driver.

11. The system of claim 10, wherein the set of NMOS transistors of a first branch of the set of branches comprises:
a first NMOS transistor coupled to a first selector line;
a second NMOS transistor coupled to a second selector line; and
a third NMOS transistor coupled to a first data line, wherein the first NMOS transistor, the second NMOS transistor and the third NMOS transistor are coupled in series between the voltage reference node and a ground node as a first series.

12. The system of claim 11, wherein the first NMOS transistor is to receive a clock signal on the first selector line, the second NMOS transistor is to receive a phase-shifted clock signal on the second selector line, and the third NMOS transistor is to receive a first data signal on the first data line.

13. The system of claim 11, wherein the set of NMOS transistors of a second branch of the set of branches comprises:
a fourth NMOS transistor coupled to the second selector line;
a fifth NMOS transistor coupled to a third selector line; and
a sixth NMOS transistor coupled to a second data line, wherein the fourth NMOS transistor, the fifth NMOS transistor, and the sixth NMOS transistor are coupled in series between the voltage reference node and the ground node as a second series, and wherein the first series is coupled in parallel with the second series.

14. The system of claim 13, wherein the first NMOS transistor is to receive a clock signal on the first selector line, the second NMOS transistor is to receive a phase-shifted clock signal on the second selector line, and the third NMOS transistor is to receive a first data signal on the first data line.

15. The system of claim 11, wherein the amplifier is a differential amplifier comprising a second input and a second output, the second output coupled to a second predriver output, the predriver further comprising:
a second voltage reference node coupled to the second input;
a second set of branches coupled to the second voltage reference node, wherein each second branch comprises a set of NMOS transistors; and
a second active inductor coupled to the second voltage reference node.

16. The system of claim 15, wherein the set of NMOS transistors of a first branch of the second set of branches comprises:
a fourth NMOS transistor coupled to the first selector line;
a fifth NMOS transistor coupled to the second selector line; and
a sixth NMOS transistor coupled to a second data line, wherein the fourth NMOS transistor, the fifth NMOS transistor, and the sixth NMOS transistor are coupled in series between the voltage reference node and the ground node.

17. The system of claim 10, wherein the active inductor comprises:
a capacitor and a resistor coupled in series between a first voltage source and the voltage reference node; and
a p-type metal-oxide semiconductor (PMOS) transistor coupled between the first voltage source and the voltage reference node, the PMOS transistor comprising a gate coupled to a node between the capacitor and the resistor.

18. The system of claim 10, wherein the output of the amplifier is coupled to the input of the driver by an impedance matching component.

19. A method of operating a predriver, the method comprising:
receiving a first clock signal, a second clock signal, and a first data signal at respective NMOS transistors of a first branch coupled to a voltage reference node;
receiving the second clock signal, a third clock signal, and a second data signal at respective NMOS transistors of a second branch coupled to the voltage reference node;
receiving the third clock signal, a fourth clock signal, and a third data signal at respective NMOS transistors of a third branch coupled to the voltage reference node;
receiving the fourth clock signal, the first clock signal, and a fourth data signal at respective NMOS transistors of a fourth branch coupled to the voltage reference node;
adjusting, using an active inductor coupled to the voltage reference node, a signal at the voltage reference node to obtain an adjusted signal;
amplifying, using an amplifier, the adjusted signal to obtain an amplified signal, the amplified signal having a first rail voltage value; and
outputting the amplified signal to a load.

20. The method of claim 19, further comprising:
receiving the first clock signal, the second clock signal, and a fifth data signal at respective NMOS transistors of a first branch coupled to a second voltage reference node;
receiving the second clock signal, the third clock signal, and a sixth data signal at respective NMOS transistors of a second branch coupled to the second voltage reference node;
receiving the third clock signal, the fourth clock signal, and a seventh data signal at respective NMOS transistors of a third branch coupled to the second voltage reference node;
receiving the fourth clock signal, the first clock signal, and an eighth data signal at respective NMOS transistors of a fourth branch coupled to the second voltage reference node;
adjusting, using a second active inductor coupled to the second voltage reference node, a second signal at the second voltage reference node to obtain a second adjusted signal;
amplifying, using the amplifier, the second adjusted signal to obtain a second amplified signal, the second amplified signal having a second rail voltage value; and
concurrent to outputting the amplified signal to the load, outputting the second amplified signal to a second load.
